(19) United States
(12) Patent Application Publication
(10) Pub. No.: US 2021/0210646 A1
(43) Pub. Date: Jul. 8, 2021

(54) BROADBAND UV-TO-SWIR PHOTODETECTORS, SENSORS AND SYSTEMS

(71) Applicant: Array Photonics, Inc., Tempe, AZ (US)

(72) Inventors: Aymeric MAROS, Tempe, AZ (US); Ferran SUAREZ, Chandler, AZ (US); Jay LIEBOWITZ, Cambridge, MA (US)

(21) Appl. No.: 17/144,604

(22) Filed: Jan. 8, 2021

Related U.S. Application Data
(60) Provisional application No. 62/958,601, filed on Jan. 8, 2020.

(51) Int. Cl. H01L 31/0304; H01L 31/0232; H01L 27/144; H01L 31/0216; H01L 31/18

(52) U.S. Cl. CPC H01L 31/03044; H01L 31/02322; H01L 31/03048; H01L 31/1848; H01L 31/02162; H01L 31/1856; H01L 27/1446

(57) ABSTRACT

Broadband photodetectors, detector arrays, sensors and systems, capable of detection and sensing ultraviolet (UV), visible (VIS) and shortwave infrared (SWIR) wavelengths of light, are disclosed. The devices may operate over a wavelength range between about 0.2 μm and 1.8 μm. In particular, the devices include a dilute nitride active layer with a bandgap within a range from 0.7 eV and 1 eV and a luminescent layer.

### CROSS-REFERENCE TO RELATED APPLICATIONS

This application claims priority to U.S. Provisional Application Ser. No. 62/958,601, filed Jan. 8, 2020, which is hereby incorporated by reference in its entirety.

### FIELD

The disclosure relates to broadband ultraviolet (UV) to shortwave infrared (SWIR) optoelectronic devices operating within the wavelength range of 0.2 μm to 1.8 μm including photodetectors and photodetector arrays, and sensors and systems employing the same.

### BACKGROUND

Broadband photodetectors, detector arrays, sensors and systems operating in the wavelength range between about 0.2 μm and 1.8 μm range have a wide range of applications, including fiber optic communications, and sensing and imaging including for military, biomedical, agricultural, industrial, environmental and scientific applications. The devices may be used for spectral analysis of a variety of materials, including food, pharmaceuticals and chemicals.

To cover such a broad wavelength range, devices made using different group-IV and compound III-V semiconductor devices must be integrated together, since detectors made from different materials only operate efficiently over narrower wavelength ranges than the desired range in many sensing applications. For example, for wavelengths in the near infrared (NIR) to SWIR, between wavelengths of about 0.9 μm and 1.8 μm, indium gallium arsenide (InGaAs) materials are usually grown on indium phosphide (InP) substrates. The composition and thickness of the InGaAs layers are chosen to provide the required functionality, such as light emission or absorption at desired wavelengths of light and are also lattice-matched or very closely lattice-matched to the InP substrate, in order to produce high quality materials that have low levels of crystalline defects, and high levels of performance. Visible and NIR wavelengths (from about 0.35 μm up to about 1.1 μm) may be detected by silicon devices on Si substrates, or by GaAs-based detectors on GaAs substrates. Gallium nitride (GaN) based devices may be used to detect UV and visible wavelengths from about 0.2 μm to 0.45 μm. However, each of these semiconductor materials has a different lattice constant, preventing monolithic integration of the materials without undertaking difficult and complex growth and processing steps. Typically, multiple different sensors or imagers must be used to provide broad spectral coverage for practical systems. Silicon detectors may be produced that can absorb UV light, either through substrate thinning, or by surface treatment using a fluorescent or phosphorescent layer that can absorb light between about 0.2 and 0.35 μm. However, the maximum absorption wavelength is 1.1 μm. Some attempts to reduce the minimum wavelength absorption for InGaAs detectors on InP substrates have been made. Detectors with absorption at wavelengths as short as 0.5 μm have been made, but the spectral responsivity in the visible range is low, and the device processing is complex, requiring careful substrate thinning Although InGaAs on InP materials currently dominates the short wavelength infrared (SWIR) photodetector market, the material system has several limitations, including the high cost of InP substrates, low yields due to fragility of the InP substrates, and limited InP wafer diameter (and associated quality issues at larger diameters). From a manufacturing perspective and an economic perspective, gallium arsenide (GaAs) represents a better substrate choice. However, the large lattice mismatch between GaAs and the InGaAs alloys required for infrared devices produces poor quality materials that compromise electrical and optical performance. Attempts have been made to produce long-wavelength (greater than 1.2 μm) materials for photodetectors on GaAs based on dilute nitride materials such as GaInNAs and GaInNAsSb. However, where device performance is reported, it has been much poorer than for InGaAs/InP devices. For example, the dilute nitride-based devices have very low spectral responsivity, which make the devices unsuited for practical sensing and photodetection applications. Furthermore, although GaAs can absorb visible wavelengths of light, when designing SWIR detectors using dilute nitride materials, absorption at wavelengths outside of the dilute nitride layer causes the short wavelength absorption of the detectors to be limited to about 0.9 μm. Other considerations for photodetectors include dark current and specific responsivity.

For example, Cheah et al., “GaAs-Based Heterojunction p-i-n Photodetectors Using Pentenary InGaAsNSb as the Intrinsic Layer”, IEEE Photon. Technol. Letts., 17(9), pp. 1932-1934 (2005), and Loke et al., “Improvement of GaInNAs p-i-n photodetector responsivity by antimony incorporation”, J. Appl. Phys. 101, 033122 (2007) report photodetectors having a responsivity of only 0.097 A/W at a wavelength of 1300 nm.
Tan et al., “GaInNAsSb/GaAs Photodiodes for Long Wavelength Applications, IEEE Electron. Dev. Letts., 32(7), pp. 919-921 (2011) describe photodiodes having a responsivity of only 0.18 A/W at a wavelength of 1300 nm.

In U.S. Application Publication No. 2016/0372624, Yanka et al. disclose optoelectronic detectors having dilute nitride layers (InGaNAsSb). Although certain parameters that relate to semiconductor material quality are described, no working detectors having practical efficiencies are taught within the broad compositional range disclosed.

To take advantage of the manufacturing scalability and cost advantages of GaAs substrates, there is continued interest in developing long-wavelength materials on GaAs that have improved optoelectronic performance. There is also interest in developing devices based on these materials that are capable of operating at visible and UV wavelengths, so that one device may be able to provide a broad wavelength range of operation that is usually covered by two or more separate devices based on different material systems.

### SUMMARY

According to the present invention, semiconductor optoelectronic devices comprise: a substrate; a first doped III-V layer overlying the substrate; an active region overlying the first doped III-V region, wherein, the active region comprises a lattice matched dilute nitride layer or a pseudomorphic dilute nitride layer; the dilute nitride layer has a bandgap within a range from 0.7 eV and 1.0 eV; and the dilute nitride layer has a minority carrier lifetime of 1 ns or greater, wherein the minority carrier lifetime is determined using time-resolved photoluminescence at 25° C.; a second doped III-V layer overlying the active region; and a luminescent layer overlying the second doped III-V layer, wherein the semiconductor optoelectronic device is configured to have a spectral responsivity within a range from 0.2 μm 1.8 μm.

According to the present invention, photodetector arrays comprise a plurality of the semiconductor optoelectronic devices of any one of claims 1 to 10.

According to the present invention, sensors comprise at least one semiconductor optoelectronic device of any one of claims 1 to 10, and at least one optical filter overlying the at least one semiconductor optoelectronic device.

According to the present invention, methods of forming semiconductor optoelectronic devices comprise: forming a substrate; forming a first doped III-V layer overlying the substrate; forming an active region overlying the first doped III-V layer, wherein, the active region comprises a lattice matched dilute nitride layer or a pseudomorphic dilute nitride layer; the dilute nitride layer has a bandgap within a range from 0.7 eV and 1.0 eV; and the dilute nitride layer has a minority carrier lifetime of 1 ns or greater, wherein the minority carrier lifetime using time-resolved photoluminescence at 25° C.; forming a second doped III-V layer overlying the active region; and forming a luminescent layer overlying the second doped III-V layer.

According to the present invention, methods of forming semiconductor optoelectronic devices comprise: forming a substrate; forming an etch-stop/release layer overlying the substrate; forming a first doped III-V layer overlying the etch-stop/release layer; forming an active region overlying the first doped III-V layer, wherein, the active region comprises a lattice matched dilute nitride layer or pseudomorphic dilute nitride layer; the dilute nitride layer has a bandgap within a range from 0.7 eV and 1.0 eV; and the dilute nitride layer has a minority carrier lifetime of 1 ns or greater; forming a second doped III-V layer overlying the active region; removing the substrate and the etch-stop/release layer; and forming a luminescent layer underlying the first doped III-V layer.

According to the present invention, semiconductor optoelectronic devices are made according to the present invention.

### BRIEF DESCRIPTION OF THE DRAWINGS

The drawings described herein are for illustration purposes only. The drawings are not intended to limit the scope of the present disclosure.

FIG. 1 shows a side view of an example of a semiconductor optoelectronic device according to the present invention.

FIG. 2 shows a side view of another example of a semiconductor optoelectronic device according to the present invention.

FIG. 3 shows a side view of another example of a semiconductor optoelectronic device according to the present invention.

FIG. 4 shows a side view of an example of a UV-enhanced photodetector according to the present invention.

FIG. 5 shows a side view of another example of a UV-enhanced photodetector according to the present invention.

FIG. 6 shows a side view of another example of a semiconductor optoelectronic device according to the present invention.

FIG. 7 shows a side view of an example of a UV-enhanced photodetector according to the present invention.

FIG. 8 shows measured responsivity curves for semiconductor optoelectronic devices according to the present invention.

FIGS. 9A and 9B are diagrams showing hybrid integration of a detector array chip with an array of readout circuits on a readout integrated circuit (ROIC) chip.

FIGS. 10A and 10B are plan views of photodetector arrays integrated with spectral filters.

### DETAILED DESCRIPTION

The following detailed description refers to the accompanying drawings that show, by way of illustration, specific details and embodiments in which the invention may be practiced. These embodiments are described in sufficient detail to enable those skilled in the art to practice the present invention. Other embodiments may be utilized, and structural, logical, and electrical changes may be made without departing from the scope of the invention. The various embodiments disclosed herein are not necessarily mutually exclusive, as some disclosed embodiments may be combined with one or more other disclosed embodiments to form new embodiments. The following detailed description is, therefore, not to be taken in a limiting sense, and the scope of the embodiments of the present invention is defined only by the appended claims, along with the full scope of equivalents to which such claims are entitled.

The term “lattice matched” as used herein means that the two referenced materials have the same lattice constant or a lattice constant differing by less than +/−0.2%. For example, GaAs and AlAs are lattice matched, having lattice constants differing by 0.12%.

The term “pseudomorphically strained” as used herein means that layers made of different materials with a lattice constant difference up to +/−2% can be grown on top of a lattice matched or strained layer without generating misfit dislocations. The lattice parameters can differ, for example, by up to +/−1%, by up to +/−0.5%, or by up to +/−0.2%.

The term “layer” as used herein, means a continuous region of a material (e.g., a semiconductor alloy) that can be uniformly or non-uniformly doped and that can have a uniform or a non-uniform composition across the region.

“Region” refers to one or more semiconductor layers. The region is identified based on the function of the region in the semiconductor device.

The term “bandgap” as used herein is the energy difference between the conduction and valence bands of a material.

The term responsivity of a material as used herein refers to the ratio of the generated photocurrent to the incident power of radiation.

The term “spectral sensitivity” or “spectral responsivity” as used herein refers to the relative efficiency of detection, of a light, signal as a function of the frequency or wavelength of the light signal.

“Active region” refers to a layer (or layers) within a device capable of processing light over a desired wavelength range. Processing is defined to be a light emission, a light receiving, a light sensing and light modulation. For example, light absorbed by an active region produces photogenerated carriers (electrons and holes).

“Overlying” is used to refer to the position of a semiconductor layer with respect to another semiconductor. A first semiconductor layer that overlies a second semiconductor layer can be adjacent and in contact with the second semiconductor layer or there can be one or more semiconductor layers between the first semiconductor layer and the semiconductor layer.

“Adjacent” refers to the position of a first semiconductor layer with respect to a second semiconductor layer such that the first and second semiconductor layers are in physical contact.

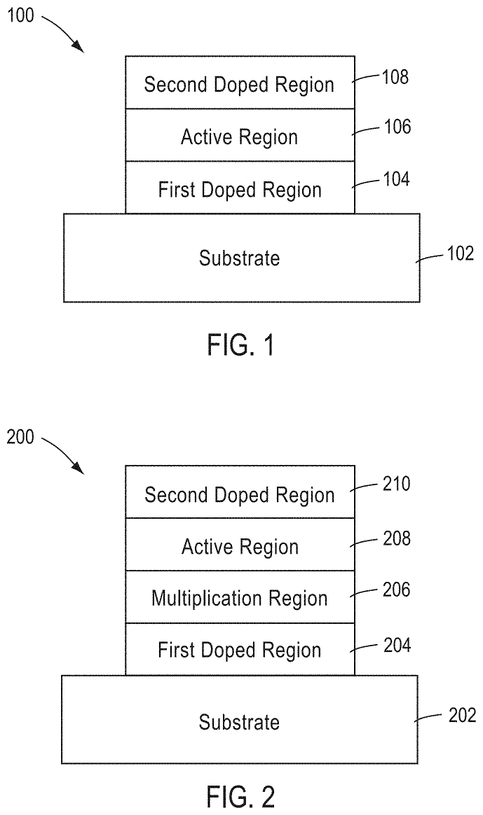

FIG. 1 shows a side view of an example of a semiconductor optoelectronic device 100 according to the present invention. Device 100 comprises a substrate 102, a first doped region 104, an active region 106, and a second doped region 108. For simplicity, each region is shown as a single layer. However, it will be understood that each region can include one or more layers with differing compositions, thicknesses, and doping levels to provide an appropriate optical and/or electrical functionality, and to improve interface quality, electron transport, hole transport and/or other optoelectronic properties.

Substrate 102 can have a lattice constant that matches or nearly matches the lattice constant of the substrates such as GaAs or Ge. The lattice constants of GaAs and Ge are 5.65 Å and 5.66 Å, respectively, and growth of III-V materials with similar compositions without defects can be grown on either substrate. The close matching of the lattice constants of Ge and GaAs allows, for example, high-quality GaAs to be epitaxially grown on a Ge surface. In some embodiments, the substrate can be GaAs. Substrate 102 may be doped p-type, or n-type, or may be a semi-insulating (SI) substrate. The thickness of substrate 102 can be chosen to be any suitable thickness, such as between about 150 μm and 750 μm. Substrate 102 can include one or more layers, for example, the substrate can include a buffered substrate, such as a buffered Si substrate that is engineered to have a lattice constant that matches or nearly matches the lattice constant of GaAs or Ge. A material such as a substrate having a lattice constant that nearly matches the lattice constant of GaAs or Ge means that the material such as the substrate has a lattice constant different than that of GaAs or Ge by less than or equal to 3%, less than 1%, or less than 0.5% of the lattice constant of GaAs or Ge. Examples of buffered silicon substrates that can provide a lattice constant approximately equal to that of GaAs or Ge include SiGe buffered Si, SiGeSn buffered Si, and rare-earth (RE) buffered Si, such as a rare-earth oxide (REO) buffered Si. A layer such as SiGe, SiGeSn, or a RE-containing layer can form a buffer layer (or lattice engineered layer) grown on a substrate such as Si having a low number of defects and/or dislocations in the buffer layer. The buffer layer can provide a lattice constant at the top of the buffer layer approximately equal to that of a GaAs or Ge substrate, facilitating the ability to form high quality III-V layers on top of the buffer layer, with a low number of defects and/or dislocations in the overlying III-V semiconductor layers and/or dilute nitride layers. A low number of defects can include comparable or fewer defects than would occur in an In_{0.53}Ga_{0.47}As layer grown on an InP substrate.

First doped region 104 can have a doping of one type and the second doped region 108 can have a doping of the opposite type. If first doped region 104 is doped n-type, second doped region 108 is doped p-type. Conversely, if first doped region 104 is doped p-type, second doped region 108 is doped n-type. Examples of p-type dopants include C and Be. Examples of n-type dopants include Si and Te. Doped region 104 and 108 cab be chosen to have a composition that is lattice matched or pseudomorphically strained with respect to the substrate. The doped region can comprise any suitable III-V material, such as GaAs, AlGaAs, GalnAs, (Al)GaInP, AlInP, (Al)GaInPAs, GaInNAs, or GaInNAsSb. The bandgap of the doped region can be selected to be larger than the bandgap of active region 106. In some embodiments, the bandgap of the doped regions, or at least a portion of the doped regions can be selected to be larger than the bandgap of GaAs such that optical absorption by the doped regions in the visible wavelength range is reduced. Doping levels can be within a range, for example, from 1×10¹⁵ cm⁻³ to 2×10¹⁹ cm⁻³.

Doping levels can be constant within a doped region, and/or the doping profile may be graded, for example, the doping level can increase from a minimum value to a maximum value as a function of the distance from the interface between the first doped region 104 and the active region 106. Doped regions 104 and 108 can have a thickness within a range, for example, from 50 nm to 3 μm, from 100 nm to 2 μm, or from 200 nm to 1 μm.

Active region 106 can include an active layer. Active region comprises at least one layer capable of processing light over a desired wavelength range. Processing is defined to be a light emission, a light receiving, a light sensing and light modulation.

The active layer can be lattice matched or pseudomorphically strained with respect to the substrate and/or to the doped regions. The bandgap of the active layer can be lower than that of the doped regions 104 and 108.

The active layer can include a dilute nitride material. A dilute nitride material can be Ga₁₋ₓInₓN_{y}As_{1-y-z}Sb_{z}, where x, y and z can be 0≤x≤0.4, 0<y≤0.07 and 0<z≤0.04, respectively. X, y and z can be 0.01≤x≤0.4, 0.02≤y≤0.07 and 0.001≤z≤0.04, respectively. In other embodiments, dilute nitride materials can have compositions as disclosed in U.S. Pat. No. 8,962,993, where x, y and z can be 0≤x≤0.24, 0.02≤y≤0.05 and 0.001≤z≤0.2, respectively. A dilute nitride material can be Ga₁₋ₓInₓN_{y}As_{1-y-z}Sb_{z}, where, for example, 0.12≤x≤0.24, 0.03≤y≤0.07 and 0.005≤z≤0.04; 0.13≤x≤0.2, 0.03≤y≤0.045 and 0.001≤z≤0.02; 0.13≤x≤0.18, 0.03≤y≤0.04 and 0.001≤z≤0.02; or 0.18≤x≤0.24, 0.04≤y≤0.07 and 0.01≤z≤0.024.

The active layer can have a bandgap within a range from 0.7 eV and 1.0 eV such that the active layer can absorb light at wavelengths up to about 1.8 μm such as, for example from 0.2 μm to 1.24 μm, or from 0.2 μm to 1.8 μm. Bismuth (Bi) may be added as a surfactant during growth of the dilute nitride material, improving material quality (such as defect density), and the device performance. The thickness of the active layer can be within a range, for example, from 0.2 μm to 10 μm. The thickness of the active layer can be within a range, for example, from 0.5 μm to 5 μm. The thickness of the active layer can be within a range, for example, from 1 μm to 4 μm, from 1 μm to 3 μm, or from 1 μm to 2 μm. The active layer can be compressively strained with respect to the substrate 102. Strain can improve device performance. For a photodetector, the parameters most relevant to device performance include the dark current, operating speed, noise, and responsivity.

Active region 106 is shown as a single layer, but it will be understood that active region 106 can include more than one dilute nitride layer, with at least two bandgaps between 0.7 eV and 1.0 eV. Examples of multi-bandgap and graded bandgap active layers are described in U.S. Application No. 62/816,718, filed on Mar. 11, 2019, which is incorporated by reference in its entirety. In some examples, active region 106 can include layers having different doping profiles. Examples of doping profiles for dilute nitride optical absorber materials are described in U.S. Application Publication No. 2016/0118526, which is incorporated by reference in its entirety.

Active region 106 and doped regions 104 and 108 form a p-i-n or an n-i-p junction. This junction provides the basic structure for operation of a device such as a photodetector or a light-emitting diode. For photodetectors, p-i-n epitaxial structures can have low background doping in the intrinsic region (active layer) of the devices which are typically operated at 0 V or at very low bias. Therefore, the active region 106 may not be deliberately doped. The active region can comprise an intrinsic layer or an unintentionally doped layer. Unintentionally doped semiconductors do not have dopants intentionally added but can include a non-zero concentration of impurities that act as dopants. The background carrier concentration of an intrinsic or unintentionally doped active layer, which is equivalent to the background dopant concentration, can be, for example, less than 1×10¹⁶ cm⁻³ (measured at room temperature, 25° C.), less than 5×10¹⁵ cm⁻³, or less than 1×10¹⁵ cm⁻³. The minority carrier lifetime (measured at 25° C.) within the active layer can be, for example, greater than 1 ns, greater than 1.5 ns, or greater 2 ns. The minority carrier lifetime can be affected by defects within the semiconductor that contribute to the background carrier concentration, as well as other defect types that can act as recombination centers but do not contribute carriers.

FIG. 2 shows a semiconductor optoelectronic device 200 with a p-i-n diode and a multiplication region 206. Device 200 is similar to device 100, but also includes a multiplication region. The purpose of the multiplication region is to amplify the photocurrent generated by the active region of a photodetector device. The structure of device 200 can provide an avalanche photodiode (APD). An APD introduces an additional p-n junction into the structure, as well as introduces an additional thickness. This allows a higher reverse bias voltage to be applied to the device, which results in carrier multiplication by the avalanche process.

Substrate 202 can have a lattice constant that matches or nearly matches the lattice constant of GaAs or Ge. The substrate can be GaAs. Substrate 202 may be doped p-type, or n-type, or may be a semi-insulating (SI) substrate. The thickness of substrate 202 can be chosen to be any suitable thickness such as, for example, between about 150 μm and 750 μm. Substrate 202 can include one or more layers, for example, a Si layer having an overlying SiGeSn buffer layer that is engineered to have a lattice constant that matches or nearly matches the lattice constant of GaAs or Ge. This can mean the substrate has a lattice constant different than that of GaAs or Ge by less than or equal to 3%, less than 1%, or less than 0.5% that of GaAs or Ge.

First doped region 204 can have a doping of one type and the second doped region 210 can have a doping of the opposite type. If first doped region 204 is doped n-type, second doped region 210 is doped p-type. Conversely, if first doped region 204 is doped p-type, second doped region 210 is doped n-type. Examples of p-type dopants include C and Be. Examples of n-type dopants include Si and Te. Doped regions 204 and 210 can be chosen to have a composition that is lattice matched or pseudomorphically strained to the substrate. The doped regions can comprise any suitable III-V material, such as GaAs, AlGaAs, GalnAs, AlInP, (Al)GaInP, (Al) GaInPAs, GaInNAs, and GaInNAsSb. The bandgap of the doped regions can be selected to be larger than the bandgap of active region 208. In some embodiments, the bandgap of the doped regions, or at least a portion of the doped regions can be selected to be larger than the bandgap of GaAs such that optical absorption by the regions in the visible wavelength range is reduced. Doping levels can be within a range, for example, from 1×10¹⁵ cm⁻³ to 2×10¹⁹ cm⁻³. Doping levels may be constant within a region and/or the doping profile may be graded, for example, the doping level can increase from a minimum value to a maximum value as a function of the distance from the interface between the second doped region 210 and the active region 208. Doped layers 204 and 210 can have a thickness, for example, within a range from 50 nm and 3 μm, from 100 nm to 2 μm, or from 200 nm to 1 μm.

Active region 208 can be lattice matched or pseudomorphically strained to the substrate and/or to the doped regions. The bandgap of active region 208 can be lower than that of the doped regions 204 and 210. Active region 208 can comprise a layer capable of processing light over a desired wavelength range. Processing is defined to be a light emission, a light receiving, a light sensing and light modulation.

Active region 208 can include at least one active layer.

An active layer can include a dilute nitride material. The dilute nitride material can be Ga₁₋ₓInₓN_{y}As_{1-y-z}Sb_{z}, where x, y and z can be 0≤x≤0.4, 0<y≤0.07 and 0<z≤0.04, respectively. X, y and z can be 0.01≤x≤0.4, 0.02≤y≤0.07 and 0.001≤z≤0.04, respectively. In other embodiments, dilute nitride materials can have compositions as disclosed in U.S. Pat. No. 8,962,993, where x, y and z can be 0≤x≤0.24, 0.02≤y≤0.05 and 0.001≤z≤0.2, respectively. A dilute nitride material can be Ga₁₋ₓInₓN_{y}As_{1-y-z}Sb_{z}, where, for example, 0.12≤x≤0.24, 0.03≤y≤0.07 and 0.005≤z≤0.04; 0.13≤x≤0.20, 0.03≤y≤0.045 and 0.001≤z≤0.02; 0.13≤x≤0.18, 0.03≤y≤0.04 and 0.001≤z≤0.02; or 0.18≤x≤0.24, 0.04≤y≤0.07 and 0.01≤z≤0.04. An active layer can have a bandgap within a range from 0.7 eV to 1.0 eV such that the active layer can absorb light at wavelengths up to 1.8 μm. Bismuth (Bi) may be added as a surfactant during growth of the dilute nitride material, improving material quality (such as defect density), and the device performance. The thickness of an active layer can be within a range, for example, from 0.2 μm to 10 μm, from 0.5 μm to 5 μm, or from 1 μm to 4 μm. An active layer can be compressively strained with respect to the substrate 202. Strain can also improve device performance. For a photodetector, the device performance of most relevance includes the dark current, operating speed, noise and responsivity.

Active region 208 is shown as a single layer, but it will be understood that active region 208 can include more than one active layer such as one or more dilute nitride layers, with at least two bandgaps between 0.7 eV and 1.0 eV. Examples of multi-bandgap and graded bandgap active layers are described in U.S. Application No. 62/816,718. In some examples, active layer 208 can include active layers with different doping profiles. Examples of doping profiles for dilute nitride optical absorber materials are described in U.S. Application Publication No. 2016/0118526.

The multiplication region 206 can be a p-type III-V region configured to amplify the current generated by the active region 208 through avalanche multiplication. Thus, for each free carrier (electron or hole) generated by the active region 208, the multiplication region 206 generates one or more carriers via the avalanche effect. Thus, the multiplication region 206 increases the total current generated by the semiconductor device 200. Multiplication region 206 can comprise a III-V material, such as GaAs or AlGaAs. In some embodiments, multiplication region 206 can include a dilute nitride layer such as GaInNAs, GaInNAsSb or GaNAsSb. Examples of semiconductor materials and structures for multiplication region 206 are described in co-pending PCT International Application No. PCT/US2019/036857 filed on Jul. 18, 2018, which is incorporated by reference in its entirety.

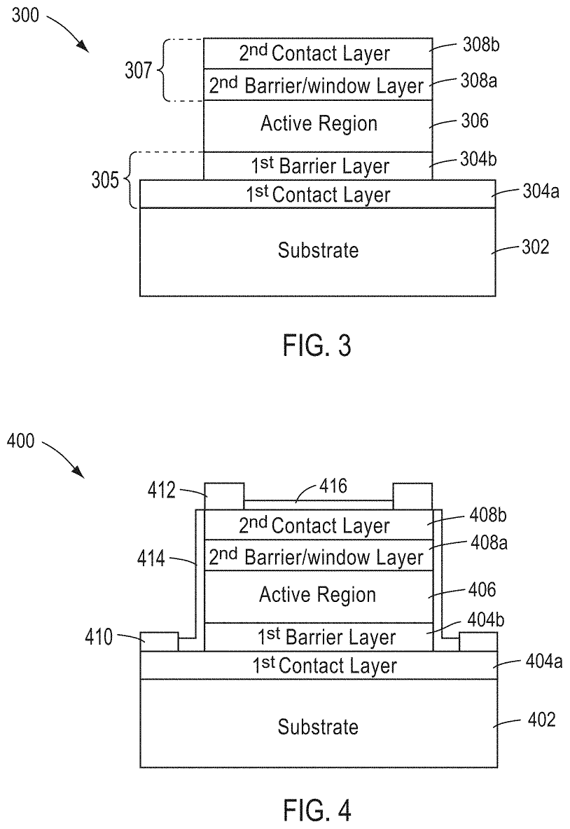

FIG. 3 shows a side view of an example of a semiconductor optoelectronic device 300 according to the present invention. Device 300 is similar to device 100 shown in FIG. 1, but each of the doped regions 305 and 307 are shown to comprise two layers. Device 300 includes a substrate 302, a first contact layer 304a, a first barrier layer 304b, an active region 306, a second barrier layer 308a, and a second contact layer 308b.

Substrate 302 can have a lattice constant that matches or nearly matches the lattice constant of GaAs or Ge. The lattice constants of GaAs and Ge are 5.65 Å and 5.66 Å, respectively, and growth of III-V materials with similar compositions without defects can be grown on either substrate. The close matching of the lattice constants of Ge and GaAs allows, for example, high-quality GaAs to be epitaxially grown on a Ge surface. In some embodiments, the substrate can be GaAs. Substrate 302 may be doped p-type, or n-type, or may be a semi-insulating (SI) substrate. The thickness of substrate 302 can be chosen to be any suitable thickness, typically between about 150 μm and 750 μm. Substrate 302 can include one or more layers, for example, the substrate can include a buffered substrate, such as a buffered Si substrate that is engineered to have a lattice constant that matches or nearly matches the lattice constant of GaAs or Ge. A material such as a substrate having a lattice constant that nearly matches the lattice constant of GaAs or Ge means that the material such as the substrate has a lattice constant different than that of GaAs or Ge by less than or equal to 3%, less than 1%, or less than 0.5% of the lattice constant of GaAs or Ge. Examples of buffered silicon substrates that can provide a lattice constant approximately equal to that of GaAs or Ge include SiGe buffered Si, SiGeSn buffered Si, and rare-earth (RE) buffered Si, such as a rare-earth oxide (REO) buffered Si. A layer such as SiGe, SiGeSn, or a RE-containing layer can form a buffer layer (or lattice engineered layer) grown on a substrate such as Si having a low number of defects and/or dislocations in the buffer layer. The buffer layer can provide a lattice constant at the top of the buffer layer approximately equal to that of a GaAs or Ge substrate, facilitating the ability to form high quality III-V layers on top of the buffer layer, with a low number of defects and/or dislocations in the III-V semiconductor layers and/or dilute nitride layers. A low number of defects can include comparable or fewer defects than would occur in an In_{0.53}Ga_{0.47}As layer grown on an InP substrate.

First contact layer 304a and first barrier layer 304b provide a first doped region 305, having a doping of one type, and second barrier/window layer 308a and second contact layer 308b provide a second doped region 307, having a doping of the opposite type. If first doped layer 305 is doped n-type, second doped layer 307 is doped p-type. Conversely, if first doped region 305 is doped p-type, second doped region 307 is doped n-type. Examples of p-type dopants include C and Be. Examples of n-type dopants include Si and Te. Doped region 305 and 307 can be chosen to have a composition that is lattice matched or pseudomorphically strained with respect to the substrate. The doped regions can comprise any suitable III-V material, such as GaAs, AlGaAs, GalnAs, AlInP, (Al)GaInP, (Al)GaInPAs, GaInNAs, and GaInNAsSb. The contact and barrier region and doped layers can have different compositions and different thicknesses. The bandgap of the doped regions and doped layers can be selected to be larger than the bandgap of active region 306. In some embodiments, the bandgap of the doped region and doped layers, or at least a portion of the doped layers can be selected to be larger than the bandgap of GaAs such that optical absorption by the doped layers in the visible wavelength range is reduced. In particular, for a device intended to be a photodetector illuminated through the top surface, second barrier/window layer 308a can include a material such as AlInP, AlGaAs, (Al)GaInP, or (Al)GaInPAs. The larger bandgap of layer 308a reduces optical absorption in this layer for visible wavelengths of light, allowing visible light to be absorbed within active region 306. This can reduce the short wavelength cutoff for a photodetector from about 0.9 μm to about 0.4 μm, thereby allowing the photodetector to have a responsivity over a broader wavelength range. The use of window/barrier layer 308a allows a reduced thickness for second contact layer 308b, further reducing the optical losses for layer 308b, through which incident light passes into the active region 306 of device 300. The doping level of first contact layer 304a can be chosen to be higher than the doping level of first barrier layer 304b. A higher doping facilitates electrical connection with a metal contact. Similarly, the doping level of second contact layer 304b can be chosen to be higher than the doping level of second barrier layer 304a. Higher doping levels facilitate electrical connection with a metal contact. Doping levels can be within a range, for example, from 1×10¹⁵ cm⁻³ to 2×10¹⁹ cm⁻³. Doping levels may be constant within a layer and/or the doping profile may be graded. For example, the doping level can increase from a minimum value to a maximum value as a function of the distance from the interface between the doped layer 308a and the active region 306. Each of barrier and contact layers 304a, 304b, 308a and 308b can independently have a thickness, for example, within a range from 50 nm to 3 μm, from 100 μm to 2 μm, or from 200 nm to 1 μm.

Active region 306 can be lattice matched or pseudomorphically strained to the substrate and/or to the barrier layers 304a and 308a. The bandgap of active region 306 can be lower than that of barrier and contact layers 304a, 304b, 308a and 308b. Active region 306 can comprise a single active layer or multiple active layers capable of processing light over a desired wavelength range. Processing is defined to be a light emission, a light receiving, a light sensing and light modulation.

An active layer can include a dilute nitride material. The dilute nitride material can be Ga₁₋ₓInₓN_{y}As_{1-y-z}Sb_{z}, where x, y and z can be 0≤x≤0.4, 0<y≤0.07 and 0<z≤0.04, respectively. X, y and z can be 0.01≤x≤0.4, 0.02≤y≤0.07 and 0.001≤z≤0.04, respectively. In other embodiments, dilute nitride materials can have compositions as disclosed in U.S. Pat. No. 8,962,993, where x, y and z can be 0≤x≤0.24, 0.02≤y≤0.05 and 0.001≤z≤0.2, respectively. A dilute nitride material can be Ga₁₋ₓInₓN_{y}As_{1-y-z}Sb_{z}, where, for example, 0.12≤x≤0.24, 0.03≤y≤0.07 and 0.005≤z≤0.04; 0.13≤x≤0.2, 0.03≤y≤0.045 and 0.001≤z≤0.02; 0.13≤x≤0.18, 0.03≤y≤0.04 and 0.001≤z≤0.02; or 0.18≤x≤0.24, 0.04≤y≤0.07 and 0.01≤z≤0.04. An active layer can have a bandgap within a range from 0.7 eV to 1.0 eV such that the active layer can absorb light at wavelengths up to 1.8 μm. Bismuth (Bi) may be added as a surfactant during growth of the dilute nitride, improving material quality (such as defect density), and the device performance. The thickness of an active layer can be, for example, within a range from 0.2 μm to 10 μm or from 1 μm to 4 μm. The minority carrier concentration of an active layer can be, for example, less than 1×10¹⁶ cm⁻³ (measured at room temperature, 25° C.), less than 5×10¹⁵ cm⁻³, or less than 1×10¹⁵ cm⁻³. Active layer 306 can be compressively strained with respect to the substrate 302. Strain can also improve device performance. For a photodetector, the parameters most relevant to device performance include the dark current, operating speed, noise and responsivity. In FIG. 3, active region 306 is shown as a single layer, but it will be understood that active region 306 can include more than one active layer such as more than one dilute nitride layer, with at least two bandgaps between 0.7 eV and 1.0 eV. Examples of multi-bandgap and graded bandgap active layers are described in U.S. Application No. 62/816,718, filed on Mar. 11, 2019. In some examples, active region 208 can include active layers with different doping profiles. Examples of doping profiles for dilute nitride optical absorber materials are described in U.S. Application Publication No. 2016/0118526.

FIG. 4. shows a side view of an example of a UV-enhanced photodetector 400 according to the present invention. Device 400 is similar to device 300. Compared to device 300, additional device layers include a first metal contact 410, a second metal contact 412, a passivation layer 414, and a luminescent layer 416 overlying a first portion of second contact layer 408b.

The semiconductor layers 402, 404a, 404b, 406, 408a and 408b correspond to layers 302, 304a, 304b, 306, 308a and 308b, respectively, of device 300. Multiple lithography and materials deposition steps may be used to form the metal contacts, passivation layer, and luminescent layer. The device has a mesa structure, produced by etching. This exposes the underlying layers. A passivation layer 414 is provided that covers the side-walls of the device and the exposed surfaces of layers so as to reduce surface defects and dangling bonds that may otherwise affect device performance. The passivation layer 414 can be formed using a dielectric material such as, for example, silicon nitride, silicon oxide, or titanium oxide.

Luminescent layer 416 is configured to absorb at ultraviolet wavelengths and to emit light at longer wavelengths such as at wavelengths that can be absorbed by active region 406 of device 400. Luminescent layer 416 can be an organic material and may be a fluorescent or a phosphorescent material that is able to absorb at UV wavelengths of light, and re-emit, either though fluorescence or phosphorescence, at visible wavelengths of light and that can be absorbed by active region 406 of device 400. Luminescent layer 416 can absorb light at wavelengths of light, for example, between about 150 nm and about 450 nm and can emit light at wavelengths between about 450 nm and 650 nm. Luminescent layer 416 can have a thickness, for example, of about 1 μm or can have a thickness between about 0.1 μm and about 2 μm.

Examples of luminescent materials include Lumigen® chemiluminescent reagent available from Beckman Coulter Company, Unichrome® phosphors described in U.S. Pat. No. 5,795,617 and available from Acton Optics and coatings, other organic materials such as those described in U.S. Pat. No. 5,986,268, and inorganic coatings such as those described by Franks in “Inorganic Phosphor Coatings for Ultraviolet Responsive Image Detectors”, MSc thesis, University of Waterloo, 2000.

Optionally, an anti-reflection or encapsulant layer (not shown) can overlie luminescent layer 416. The antireflection or encapsulant layer can include dielectric materials that are transparent at ultraviolet wavelengths as low as about 0.2 μm such as Al₂O₃, and MgF₂, and the thickness can be, for example, from about 10 nm and 400 nm.

As shown in FIG. 4, a first metal contact 410 overlies a portion of the first contact layer 404a. A second metal contact 412 overlies a second portion of second contact layer 408b. Metallization schemes for contacting to n-doped and p-doped materials are known to those ordinarily skilled in the art. Photodetector 400 can be illuminated from the top surface of the device, i.e. through the interface between luminescent layer 416 (or an overlying antireflection/encapsulation layer) and air.

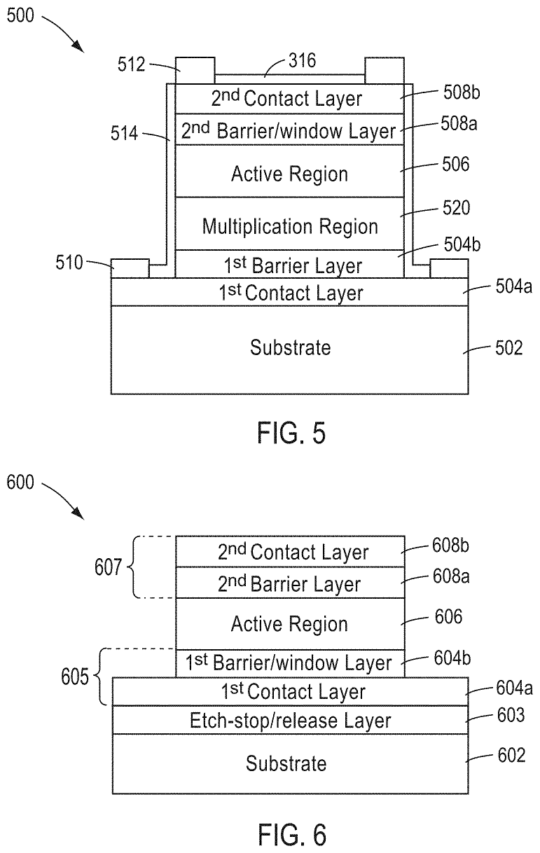

FIG. 5 shows a side view of an example of a UV-enhanced avalanche photodetector 500 according to the present invention. Device 500 is similar to device 400 but includes an additional multiplication region 520 underlying active region 506 and overlying barrier layer 504b. Examples of semiconductor materials and structures for multiplication region 520 are described in co-PCT International Application No. PCT/US2019/036857 filed on Jul. 14, 2018. The UV-enhanced avalanche photodetector 500 shown in FIG. 5 includes substrate 502, first contact layer 504a, first barrier layer 504b, multiplication region 520, active region 506, second barrier/window layer 508a, second contact layer 508b, luminescent layer 316, first metal contact 510, second metal contact 512, and passivation layer 514.

FIG. 6 shows a side view of a semiconductor optoelectronic device 600 according to the present invention. Device 600 is similar to device 300, but device 600 is configured to be illuminated through the bottom side of the device, as opposed to through the top surface as in in device 300. Device 600 includes a substrate 602, an etch stop and release layer 603, a first doped region 605 including a first contact layer 604a and a first barrier/window layer 604b, an active region 606, and a second doped region 607 including a second barrier layer 608a and a second contact layer 608b.

Substrate 602 can have a lattice constant that matches or nearly matches the lattice constant of GaAs or Ge. The lattice constants of GaAs and Ge are 5.65 Å and 5.66 Å, respectively, and growth of III-V materials with similar compositions without defects can be grown on either substrate. The close matching of the lattice constants of Ge and GaAs allows, for example, high-quality GaAs to be epitaxially grown on a Ge surface. In some embodiments, the substrate can be GaAs. Substrate 602 may be doped p-type, or n-type, or may be a semi-insulating (SI) substrate. The thickness of substrate 602 can be chosen to be any suitable thickness. Substrate 602 can include one or more layers, for example, the substrate can include a buffered substrate, such as a buffered Si substrate that is engineered to have a lattice constant that matches or nearly matches the lattice constant of GaAs or Ge. A material such as a substrate having a lattice constant that nearly matches the lattice constant of GaAs or Ge means that the material such as the substrate has a lattice constant different than that is less than or equal to 3%, less than 1%, or less than 0.5% of the lattice constant of GaAs or Ge. Examples of buffered silicon substrates that can provide a lattice constant approximately equal to that of GaAs or Ge include SiGe buffered Si, SiGeSn buffered Si, and rare-earth (RE) buffered Si, such as a rare-earth oxide (REO) buffered Si. A layer such as SiGe, SiGeSn, or a RE-containing layer can form a buffer layer (or lattice engineered layer) grown on a substrate such as Si having a low number of defects and/or dislocations in the buffer layer. The buffer layer can provide a lattice constant at the top of the buffer layer approximately equal to that of a GaAs or Ge substrate, facilitating the ability to form high quality III-V layers on top of the buffer layer, with a low number of defects and/or dislocations in the III-V semiconductor layers and/or dilute nitride layers. A low number of defects can include comparable or fewer defects than would occur in an In_{0.53}Ga_{0.47}As layer grown on an InP substrate.

Etch stop/release layer 603 can be provided to allow removal of substrate 602 through a combination of physical and chemical methods. Etch-stop/release layer 603 can be lattice matched or pseudomorphically strained with respect to substrate 602. The composition of layer 603 can be chosen to have a different etch chemistry than that of substrate 602 and first contact layer 604a. For example, using a GaAs substrate 602, layer 603 can include AlInP and GaInP. P-containing layers have a high etch selectivity with As-containing layers, allowing a layer of one type to be removed chemically, and therefore substrate 602 and etch-stop/release layer 603 may both be removed from device 600. Substrate removal is necessary for a bottom-illuminated device, because the substrate would otherwise prevent light with wavelengths less than about 0.9 μm being absorbed by active region 606. A comprehensive list of wet etchants, etch rates, and selectivity relationships is provided in Clawson, Materials Science and Engineering, 31 (2001) 1-438, Elsevier Science B.V.

First contact layer 604a and first barrier/window layer 604b provide a first doped region 605, having a doping of one type, and second barrier layer 608a and second contact layer 608b provide a second doped region 607, having a doping of the opposite type. If first doped region 605 is doped n-type, second doped region 607 is doped p-type. Conversely, if first doped region 605 is doped p-type, second doped region 607 is doped n-type. Examples of p-type dopants include C and Be. Examples of n-type dopants include Si and Te. Doped regions 605 and 607 can be chosen to have a composition that is lattice matched or pseudomorphically strained with respect to the substrate. The doped region can comprise any suitable III-V material, such as GaAs, AlGaAs, GalnAs, AlInP, (Al)GaInP, (Al)GaInPAs, GaInNAs, and GaInNAsSb. The contact and barrier layers can independently have different compositions and different thicknesses. The bandgap of the doped layers can be selected to be larger than the bandgap of active region 606. In some embodiments, the bandgap of the doped layers, or at least a portion of the doped layers can be selected to be larger than the bandgap of GaAs such that optical absorption by the layers in the visible wavelength range is reduced. In particular, for a device intended to be a photodetector illuminated through the bottom surface, first barrier/window layer 604b can include a material such as AlInP, AlGaAs, (Al)GaInP, or (Al)GaInPAs. The larger bandgap of first barrier/window layer 604b reduces optical absorption in this layer for visible wavelengths of light, allowing them to be absorbed within active region 606. This can reduce the short wavelength cutoff for a photodetector from about 0.9 μm to about 0.4 μm, thereby allowing the photodetector to have a responsivity over a broader wavelength range. The use of window/barrier layer 604b allows a reduced thickness for second contact layer 604a, further reducing the optical losses for layer 604a, through which incident light passes into the active region 606 of device 600. The doping level of first contact layer 604a can be chosen to be higher than the doping level of first barrier/window layer 604b. A higher doping facilitates electrical connection with a metal contact.

Similarly, the doping level of second contact layer 608b can be chosen to be higher than the doping level of second barrier layer 608a. Higher doping levels facilitate electrical connection with a metal contact. Doping levels can be within a range, for example, from 1×10¹⁵ cm⁻³ to 2×10¹⁹ cm⁻³. Doping levels may be constant within a region or layer and/or the doping profile may be graded, for example, the doping level can increase from a minimum value to a maximum value as a function of the distance from the interface between the doped layer 608a and the active region 606. Each of barrier and contact layers 604a, 604b, 608a and 608b can independently have a thickness, for example, within a range from 50 nm to 3 μm, from 100 nm to 2 μm, or from 200 nm to 1 μm.

Active layer 606 can be lattice matched or pseudomorphically strained with respect to the substrate and/or to the barrier layers. The bandgap of active μm 606 can be lower than that of barrier and contact layers 604a, 604b, 608a and 608b. Active μm 606 can comprise a layer capable of processing light over a desired wavelength range. Processing is defined to be a light emission, a light receiving, a light sensing and light modulation.

Active region 606 can include one or more active layers. An active layer can include a dilute nitride material. The dilute nitride material can be Ga₁₋ₓInₓN_{y}As_{1-y-z}Sb_{z}, where x, y and z can be 0≤x≤0.4, 0<y≤0.07 and 0<z≤0.04, respectively. X, y and z can be 0.01≤x≤0.4, 0.02≤y≤0.07 and 0.001≤z≤0.04, respectively. In other embodiments, dilute nitride materials can have compositions as disclosed in U.S. Pat. No. 8,962,993, where x, y and z can be 0≤x≤0.24, 0.02≤y≤0.05 and 0.001≤z≤0.2, respectively. A dilute nitride material can be Ga₁₋ₓInₓN_{y}As_{1-y-z}Sb_{z}, where, for example, 0.12≤x≤0.24, 0.03≤y≤0.07 and 0.005≤z≤0.04; 0.13≤x≤0.2, 0.03≤y≤0.045 and 0.001≤z≤0.02; 0.13≤x≤0.18, 0.03≤y≤0.04 and 0.001≤z≤0.02; or 0.18≤x≤0.24, 0.04≤y≤0.07 and 0.01≤z≤0.04. An active layer can have a bandgap within a range from 0.7 eV to 1.0 eV such that the active layer can absorb light at wavelengths up to 1.8 μm. Bismuth (Bi) may be added as a surfactant during growth of the dilute nitride, improving material quality (such as defect density), and the device performance. The thickness of an active layer can be, for example, within a range from 0.2 μm to 10 μm or from 1 μm to 4 μm. The carrier concentration of an active layer can be, for example, less than 1×10¹⁶ cm⁻³ (measured at room temperature, 25° C.), less than 5×10¹⁵ cm⁻³, or less than 1×10¹⁵ cm⁻³. An active layer can be compressively strained with respect to the substrate 602. Compressive strain can also improve device performance. For a photodetector, the parameters most relevant to device performance include the dark current, operating speed, noise and responsivity. Active region 606 is shown as a single layer, but it will be understood that active region 606 can include more than one active layer such as more than one dilute nitride region, with at least two bandgaps between 0.7 eV and 1.0 eV. Examples of multi-bandgap and graded bandgap active layers are described in U.S. Application No. 62/816,718, filed on Mar. 11, 2019. In some examples, active region 606 can include active layers with different doping profiles. Examples of doping profiles for dilute nitride optical active layers are described in U.S. Application Publication No. 2016/0118526.

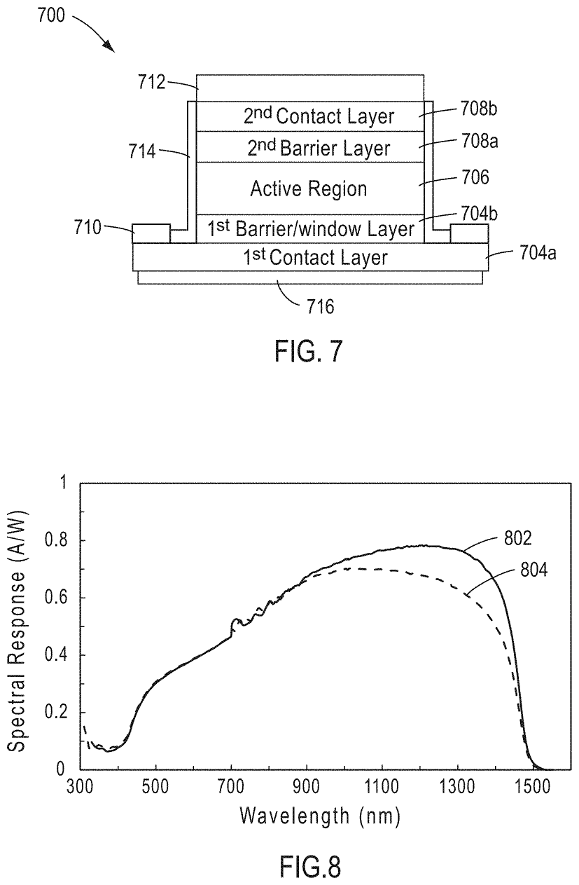

FIG. 7 shows a side view of an example of a photodetector 700 according to the present invention. Device 700 is similar to device 600. Compared to device 600, substrate 602 and etch/step release layer 603 have been removed. Additional device layers include a first metal contact 710, a second metal contact 712, a passivation layer 714, and a luminescent layer 716 underlying to a first portion of first contact layer 704a.

The semiconductor layers/regions 704a, 704b, 706, 708a and 708b correspond to layers/regions 604a, 604b, 606, 608a and 608b, respectively, of device 600. Multiple lithography and materials deposition steps may be used to form the metal contacts, passivation layer, and antireflection coating. The device has a mesa structure, produced by etching. This exposes the underlying layers. A passivation layer 714 is provided that covers the side-walls of the device and the exposed surfaces of layers and/or regions so as to reduce surface defects and dangling bonds that may otherwise affect device performance. The passivation layer 714 can be formed using one or more dielectric materials including, for example, aluminum oxide, silicon nitride, silicon oxide, and titanium oxide.

Luminescent layer 716 absorbs ultraviolet wavelengths and emits light at longer (visible) wavelengths that can be absorbed by active region 706 of device 700. Luminescent layer 716 can be an organic material and can be a fluorescent or a phosphorescent material that is able to absorb UV wavelengths of light, and re-emit, either though fluorescence or phosphorescence, visible wavelengths of light that can be absorbed by the active region 706 of device 700. For example, luminescent layer can absorb light at wavelengths of light between about 150 nm and about 450 nm and emit light at wavelengths between about 450 nm and 650 nm. Luminescent layer 716 can have a thickness, for example, of about 1 μm or can have a thickness between about 0.1 μm and about 2 μm.

Examples of luminescent materials include Lumigen® chemiluminescent reagent available from Beckman Coulter Company, Unichrome® phosphors described in U.S. Pat. No. 5,795,617 and available from Acton Optics and coatings, other organic materials such as those described in U.S. Pat. No. 5,986,268, and inorganic coatings such as those described by Franks in “Inorganic Phosphor Coatings for Ultraviolet Responsive Image Detectors”, MSc thesis, University of Waterloo, 2000.

Optionally, an anti-reflection or encapsulant layer (not shown) can underlie luminescent layer 716. The antireflection or encapsulant layer can include dielectric materials that are transparent at ultraviolet wavelengths as low as about 0.2 μm such as Al₂O₃, and MgF₂.

A first metal contact 710 overlies a portion of the first contact layer 704a. A second metal contact 712 overlies a second portion of second contact layer 708b. Metallization schemes for contacting to n-doped and p-doped materials are known to those ordinarily skilled in the art. Photodetector 700 can be illuminated via the top surface of the device, i.e. through the interface between luminescent layer 716 (or an underlying antireflection layer) and air.

FIG. 8 shows responsivity curves for two semiconductor photodetectors fabricated according to the present invention, with structures according to FIG. 3. No luminescent coating was applied to the illumination surface of these devices. Devices were fabricated by growing a GaInNAsSb absorber layer on a GaAs substrate by molecular beam epitaxy (MBE). The GaInNAsSb layer was compressively strained, with an XRD peak splitting of 600 arcsec or 800 arcsec between the GaInNAsSb dilute nitride peak and the GaAs substrate peak. Responsivity curve 802 is for a device having a 2 μm-thick GaInNAsSb dilute nitride layer, while responsivity curve 804 is for a device having a 1.2 μm-thick GaInNAsSb dilute nitride layer. The long-wavelength cut-off for the detectors was about 1.48 μm (1480 nm) and the short-wavelength cut-off was about 0.44 μm (4400). The short-wavelength cut-off is defined as the shortest wavelength of light that may be absorbed to generate photocarriers that may be collected by an external circuit connected to the electrodes of the photodetector. The long-wavelength cut-offs is defined as the maximum wavelength that may be absorbed and generates photogenerated electrons and holes. This short wavelength cutoff is ideal for use with a luminescent layer, providing a photodetector with a responsivity at wavelengths as short as 0.2 μm that can be used in broadband spectral sensing applications.

Responsivity was measured using a broad-band halogen lamp, with light monochromatized at 10 nm wavelength steps and calibrated using a NIST traceable InGaAs detector.

Arrays of photodetectors may also be formed using photodetectors provided by the present disclosure. An array of top-illuminated devices (such as device 400 or 500) may be surface-mounted to and wire-bonded to an underlying substrate and read-out circuitry. An array of bottom-illuminated devices (such as device 700) may be flipped vertically such that the bottom surface faces up and provides the illumination surface, and the top surface faces toward an underlying substrate and read-out circuitry. Devices may be electrically connected to the readout circuitry using an array of indium bumps on each detector (or pixel) of an array and the readout circuitry. For an array of detectors, the collected signals may be amplified by a readout integrated circuit (ROIC) comprising a transistor or a trans-impedance amplifier to form a Focal Plane Array (FPA).

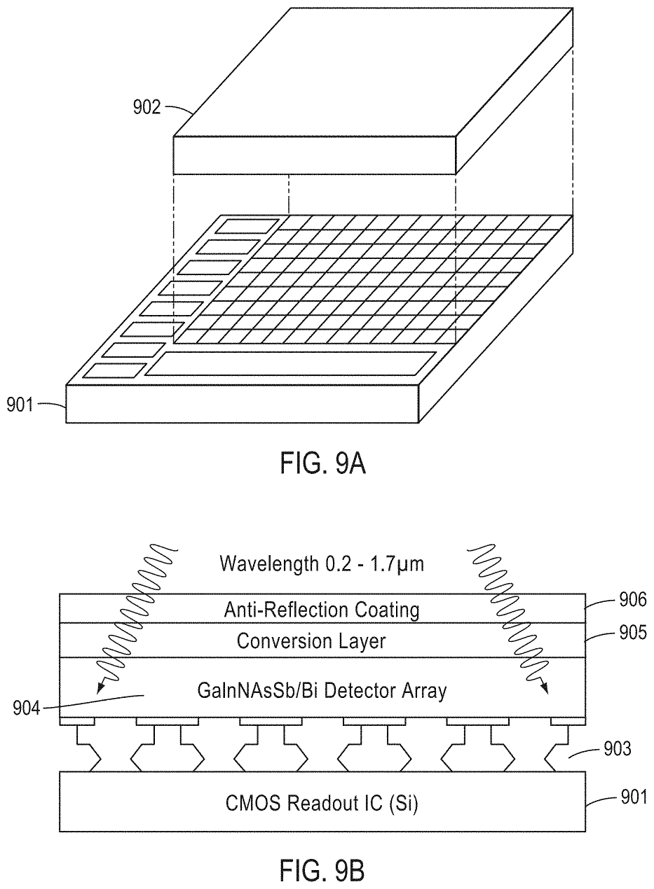

Examples of photodetector arrays are shown in FIGS. 9A and 9B. FIG. 9A shows a perspective view of a photodetector array including CMOS readout IC 901, and photodetector array 902. FIG. 9B shows a cross-sectional view of CMOS readout IC 901 interconnected to photodetector array 902 through interconnects 903. Photodetector array 902 includes an array of photodetectors provided by the present invention 904, a conversion layer 905, and an antireflection coating 906.

To function as a spectral sensor, the incident light on a photodetector or photodetector array may be spectrally filtered. In an array of photodetectors, because luminescence from the luminescent material associated with UV light absorption is emitted at a visible wavelength, some photodetectors in an array may be coated with luminescent material, and thereby are UV-enhanced photodetectors, while other photodetectors in an array may not be coated with a luminescent material, such that only a selected number of pixels within the array are sensitive to UV light.

More generally, in some embodiments, a photodetector array may be divided into sub-regions, with a different spectral filter overlying each of the sub-regions such that each sub-region is sensitive to a selected range of incident wavelengths. At least one optical filter overlies the photodetector array. At least one sub-region of the photodetector array includes UV-enhanced photodetectors.

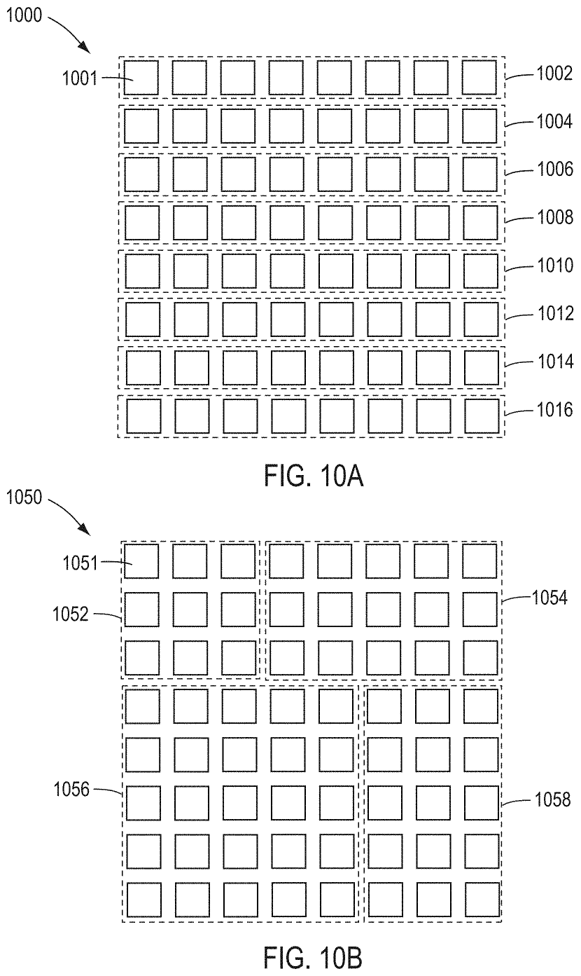

FIG. 10A shows an example of a photodetector array 1000 comprising a plurality of pixels 1001 with overlying optical filters. Each of the pixels comprises a photoreactor device according the present invention. Optical filters 1002, 1004, 1006, 1008, 1010, 1012, 1014 and 1016 are disposed over a selected portion of the photodetector detector array and filter the light incident on the underlying pixels of the photodetector array. For example, as shown in FIG. 10A, each optical filter is disposed over eight (8) pixels. The optical filters, each having a different spectral (or wavelength) transmission range or band, overlie different portions of array 1000 such that each sub-region of the array is capable of detecting light at different wavelength ranges. For example, optical filter 1002 can have a first lower wavelength cutoff and a first upper wavelength cutoff, defining a first wavelength range transmitted by optical filter 1002. Optical filter 1004 can have a second lower wavelength cutoff and a second upper wavelength cutoff, defining a second wavelength range transmitted by optical filter 1004. Optical filter 1006 can have a third lower wavelength cutoff and a third upper wavelength cutoff, defining a third wavelength range transmitted by optical filter 1006. Optical filter 1008 can have a fourth lower wavelength cutoff and a fourth upper wavelength cutoff, defining a fourth wavelength range transmitted by optical filter 1008. Optical filter 1010 can have a fifth lower wavelength cutoff and a fifth upper wavelength cutoff, defining a fifth wavelength range transmitted by optical filter 1010. Optical filter 1012 can have a sixth lower wavelength cutoff and a sixth upper wavelength cutoff, defining a sixth wavelength range transmitted by optical filter 1012. Optical filter 1014 can have a seventh lower wavelength cutoff and a seventh upper wavelength cutoff, defining a seventh wavelength range transmitted by optical filter 1014. Optical filter 1016 can have an eighth lower wavelength cutoff and an eighth upper wavelength cutoff, defining an eighth wavelength range transmitted by optical filter 1016. Each of the wavelength ranges can be different.

FIG. 10B shows another example of a photodetector array 1050 comprising a plurality of pixels 1051. Each of the pixels comprises a photodetector provided by the present disclosure. Optical filters 1052, 1054, 1056, and 1058, are disposed over different portions of the photodetector array and filter the light incident on the different portions of the photodetector array. The optical filters, each having a different spectral transmission band, overlie different portions of photodetector array 1050 such that each sub-region of the array is configured to detect light at different wavelength ranges.

The number of pixels 1001/1051 underlying each of the optical filters may vary, for example, according to the sensitivity of the pixels at different wavelengths (or wavelength ranges) and/or the power of incident light at the wavelength or wavelength range. An electrical signal for each wavelength range, (and corresponding sub-region of device 1000 or device 1050) to be measured may be generated by a single pixel 1001, or a plurality of pixels underlying each filter region of device 1000 or device 1050. A larger number of pixels may be used for light detection at wavelengths where the responsivity (measured in A/W) is lower and a fewer number of pixels may be used for light detection at wavelengths where the responsivity is higher.

In some embodiments, an optical filter can have a fixed transmission wavelength for all pixels underlying the optical filter. An optical filter may include multiple different dielectric layers with different refractive indices and of desired thicknesses to allow a desired transmission wavelength range. In other embodiments, an optical filter may be a variable optical filter, having a lower and an upper wavelength cutoff defining a wavelength transmission range, where the transmission through the optical filter may vary spatially across the surface of the optical filter, with narrower and different sub-wavelength ranges within the broader wavelength range being transmitted to each underlying pixel. For example, a first pixel may receive light a first wavelength range, and a second pixel may receive light in a second wavelength range. This can increase the number of different wavelength ranges (spectral bands) that may be measured and resolved by device 1000 or device 1050. A variable optical filter may be achieved for example, by varying the thickness of one or more of the optical filter layers across the filter. The thickness change may be continuous, for example using a wedge filter, or it may be discrete, with different layer thicknesses used above each individual pixel underlying the filter. Examples of wedge-like filters are described in U.S. Pat. No. 7,575,860. Other optical filter designs having different thicknesses that are capable of providing variable transmission characteristics are described in U.S. Pat. No. 9,261,634, and in U.S. Pat. No. 10,170,509.

Combinatorial etching and deposition techniques may be used to produce a multi-level wavelength filter across an array.

Spectral filtering may also be achieved using a diffraction grating to disperse light of different wavelength across an array, or to select a specific and tunable narrow wavelength band incident on a single photodetector. The grating may be a reflection grating or a transmission grating. Gratings are periodic structures that function to diffract different wavelengths of light from a common input path into different angular output paths. For an array of photodetectors, different wavelengths can be received by different pixels of the array, according the angular path between the grating and pixels. For a single photodetector, the grating may be rotated to steer different wavelengths of light onto a single photodetector. An example of a transmission grating is a surface relief transmission grating. Another example of a transmission grating is a volume phase holographic (VPH) grating. A VPH grating can be formed in a layer of transmissive material, such as a dichromated gelatin, which is sealed between two layers of clear glass or fused silica. The phase of incident light is modulated as it passes through the optically thick film that has a periodic differential hardness or refractive index. This is in contrast to a conventional grating in which the depth of a surface relief pattern modulates the phase of the incident light.

To fabricate optoelectronic devices provided by the present disclosure, a plurality of layers can be deposited on a substrate in a materials deposition chamber such as an MBE and/or MOCVD deposition chamber. The plurality of layers may include active layers, doped layers, contact layers, etch stop layers, release layers (i.e., layers designed to release the semiconductor layers from the substrate when a specific process sequence, such as chemical etching, is applied), buffer layers, or other semiconductor layers.

The plurality of layers can be deposited, for example, by molecular beam epitaxy (MBE) or by metal-organic chemical vapor deposition (MOCVD). Combinations of deposition methods may also be used.

A semiconductor optoelectronic device can be subjected to one or more thermal annealing treatments after growth. For example, a thermal annealing treatment can include the application of a temperature within a range from 400° C. to 1000° C. for from 10 seconds to 10 hours. Thermal annealing may be performed in an atmosphere that includes air, nitrogen, arsenic, arsine, phosphorus, phosphine, hydrogen, forming gas, oxygen, helium and any combination of the preceding materials.

Devices provided by the present disclosure can comprise a GaInNAsSb active layer overlying a GaAs substrate. The GaInNAsSb layer can be compressively strained with respect to the GaAs substrate. For example, the XRD peak slitting between the GaInNAsSb peak and the GaAs substrate peak can be, for example, from 600 arcsec to 1,000 arcsec, from 600 arcsec to 800 arc sec, or from 650 arcsec to 750 arcsec.

A dilute nitride layer such as a GaInNAsSb layer can have an intrinsic or unintentional doping equivalent to a doping concentration, for example, less than 1×10¹⁶ cm⁻³, less than 5×10¹⁵ cm⁻³, or less than 1×10¹⁵ cm⁻³, measured at room temperature (25° C.). A dilute nitride layer such as a GaInNAsSb layer can have an intrinsic or unintentional doping equivalent to a doping concentration, for example, from 0.5×10¹⁴ cm⁻³ to 1×10¹⁶ cm⁻³ or from 1×10¹⁵ cm⁻³ to 5×10¹⁵ cm⁻³, measured at room temperature (25° C.).

A dilute nitride layer such as a GaInNAsSb layer can have a minority carrier lifetime, for example, from 1.0 ns to 3.0 ns, from 1.5 ns to 2.5 ns, or from 1.5 ns to 2.0 ns. A dilute nitride layer such as a GaInNAsSb layer can have a minority carrier lifetime, for example, greater than 1.0 ns, greater than 1.5 ns, greater than 2.0 ns, or greater than 2.5 ns. To determine the minority carrier lifetime of the GaInNAsSb layer, time-resolved photoluminescence (TRPL) may be used. The TRPL kinetics are measured at room temperature (25° C.) at an excitation wavelength of 970 nm, with an average CW power of 0.250 mW, and a pulse duration of 200 fs generated by a Ti:Sapphire:OPA laser with a pulse repetition rate of 250 kHz and a laser beam diameter at the sample of 1 mm.

A dilute nitride layer such as a GaInNAsSb layer can have a bandgap, for example, from 0.7 eV to 1.0 eV, such as from 0.75 eV to 0.95 eV, or from 0.7 eV to 0.8 eV.

The absorption bandwidth of a dilute nitride layer such as a GaInNAsSb layer can have a full width half maximum, for example, from 50 nm to 150 nm, from 50 nm to 125 nm, from 50 nm to 70 nm, or from 75 nm to 125 nm, as determined by photoluminescence.

The dilute nitride layer such as a GaInNAsSb layer can have a thickness, for example, from 0.25 μm to 3.0 μm, from 0.5 μm to 2.0 μm, or from 0.5 μm to 1.0 μm.

A device such as a photodetector can have a diameter, for example, from 20 μm to 3 mm, from 0.5 mm to 2.5 mm, or from 1 mm to 2 mm. A device such as a photodetector can have a diameter, for example, greater than 20 μm, greater than 100 μm, greater than 500 μm, greater than 1 mm, or greater than 2 mm.

A UV-enhanced photodetector having a dilute nitride active layer can have the structure shown in FIG. 4. The substrate can be a semi-insulating GaAs substrate, the first barrier layer can be a p-doped GaAs layer having a thickness from 0.05 μm to 0.15 μm and a doping level from 1×10¹⁷ cm⁻³ to 1×10¹⁹ cm⁻³, the second barrier/window layer can be an n-doped InAlP layer having a thickness from 0.05 μm to 0.15 μm and a doping level from 1×10¹⁷ cm⁻³ to 1×10¹⁹ cm⁻³, and the active layer can be a GaInNAsSb layer having a bandgap from 0.7 eV to 1.0 eV, and a thickness from 0.25 μm to 3.0 μm. The XRD splitting between the GaInNAsSb peak ant the GaAs substrate can be from 600 arcsec to 1000 arcsec. The Luminescent layer may have a thickness of about 1 μm or can have a thickness between about 0.1 μm and about 2 μm.

A UV-enhanced photodetector having a dilute nitride active layer can have the structure shown in FIG. 7. The substrate can be a semi-insulating GaAs substrate, the first barrier/window layer can be a p-doped InAlP layer having a thickness from 0.05 μm to 0.15 μm and a doping level from 1×10¹⁷ cm⁻³ to 1×10¹⁹ cm⁻³, the second barrier layer can be an n-doped GaAs layer having a thickness from 0.05 μm to 0.15 μm and a doping level from 1×10¹⁷ cm⁻³ to 1×10¹⁹ cm⁻³, and the active layer can be a GaInNAsSb layer having a bandgap from 0.7 eV to 1.0 eV, and a thickness from 0.25 μm to 3.0 μm. The XRD splitting between the GaInNAsSb peak and the GaAs substrate can be from 600 arcsec to 1000 arcsec. The Luminescent layer may have a thickness of about 1 μm or may have a thickness between about 0.1 μm and about 2 μm.

Spectral sensors can have an array of photodetectors as shown in FIG. 4 and/or FIG. 7 and with an overlying spectrally selective element such as a grating or a multi-level filter.

The present disclosure includes the Appendix entitled Dilute Nitride Photodetector Arrays for Sensing Applications, including pages 1-7. The Appendix is incorporated by reference in its entirety.

Finally, it should be noted that there are alternative ways of implementing the embodiments disclosed herein. Accordingly, the present embodiments are to be considered as illustrative and not restrictive. Furthermore, the claims are not to be limited to the details given herein and are entitled their full scope and equivalents thereof.

1. A semiconductor optoelectronic device, comprising:
a substrate;
a first doped III-V layer overlying the substrate;
an active region overlying the first doped III-V region, wherein the active region comprises a lattice matched dilute nitride layer or a pseudomorphic dilute nitride layer having a bandgap within a range from 0.7 eV and 1.0 eV and a minority carrier lifetime of 1 ns or greater, wherein the minority carrier lifetime is determined using time-resolved photoluminescence at 25° C.;
a second doped III-V layer overlying the active region; and
a luminescent layer overlying the second doped III-V layer,
wherein the semiconductor optoelectronic device is configured to have a spectral responsivity within a range from 0.2 μm 1.8 μm.

2. The semiconductor optoelectronic device of claim 1, wherein the spectral responsivity is within a range from 0.2 μm to 1.24 μm.

3. The semiconductor optoelectronic device of claim 1, wherein the dilute nitride layer has a compressive strain within a range from 0% and 0.4% with respect to the substrate, wherein the compressive strain is determined by XRD.

4. The semiconductor optoelectronic device of claim 1, wherein the dilute nitride layer has a minority carrier lifetime of 1 ns or greater, wherein the minority carrier lifetime is determined using time-resolved photoluminescence.

5. The semiconductor optoelectronic device of claim 1, wherein the substrate comprises GaAs, AlGaAs, Ge, SiGeSn, or buffered Si.

6. The semiconductor optoelectronic device of claim 1, wherein the dilute nitride layer has a lattice constant less than 3% the lattice constant of GaAs or Ge.

7. The semiconductor optoelectronic device of claim 1, wherein the dilute nitride layer comprises GaInNAs, GaNAsSb, GaInNAsSb, GaInNAsBi, GaNAsSbBi, GaNAsBi, or GaInNAsSbBi.

8. The semiconductor optoelectronic device of claim 1, wherein the dilute nitride layer comprises Ga₁₋ₓInₓN_{y}As_{1-y-z}Sb_{z}, wherein 0≤x≤0.4, 0<y≤0.07, and 0<z≤0.04.

9. The semiconductor optoelectronic device of claim 1, wherein the dilute nitride layer comprises Ga₁₋ₓInₓN_{y}As_{1-y-z}Sb_{z}, wherein:
0.12≤x≤0.24, 0.03≤y≤0.07, and 0.001≤z≤0.02;
0.12≤x≤0.24, 0.03≤y≤0.07, and 0.005≤z≤0.04;
0.13≤x≤0.20, 0.03≤y≤0.045, and 0.001≤z≤0.02;
0.13≤x≤0.18, 0.03≤y≤0.04, and 0.001≤z≤0.02; or
0.18≤x≤0.24, 0.04≤y≤0.07, and 0.01≤z≤0.04.

10. The semiconductor optoelectronic device of claim 1, wherein the dilute nitride layer has a thickness within a range from 0.2 μm to 10 μm.

11. The semiconductor optoelectronic device of claim 1, further comprising a photodetector.

12. A photodetector array comprising a plurality of the semiconductor optoelectronic devices of claim 1.

13. A sensor comprising at least one semiconductor optoelectronic device of claim 1, and at least one optical filter overlying the at least one semiconductor optoelectronic device.

14. The sensor of claim 13, comprising:
a first plurality of pixels and a first optical filter characterized by a first wavelength transmission range overlying the first plurality of pixels; and
a second plurality of pixels and a second optical filter characterized by a second wavelength transmission range overlying the second plurality of pixels,
wherein each of the first and second plurality of pixels comprises the semiconductor optoelectronic device of claim 1,
wherein the first wavelength transmission range is different from the second wavelength transmission range.

15. The sensor of claim 14, wherein the first plurality of pixels comprises a different number of pixels than the second plurality of pixels.

16. A method of forming a semiconductor optoelectronic device, comprising:
forming a substrate;
forming a first doped III-V layer overlying the substrate;
forming an active region overlying the first doped III-V layer, wherein the active region comprises a lattice matched dilute nitride layer or a pseudomorphic dilute nitride layer having a bandgap within a range from 0.7 eV and 1.0 eV and a minority carrier lifetime of 1 ns or greater, wherein the minority carrier lifetime is determined using time-resolved photoluminescence at 25° C.;
forming a second doped III-V layer overlying the active region; and
forming a luminescent layer overlying the second doped III-V layer, wherein the semiconductor optoelectronic device is configured to absorb wavelengths between 0.2 μm and 1.8 μm.

17. The method of claim 16, wherein the semiconductor optoelectronic device is configured to absorb wavelengths between 0.2 μm and 1.24 μm.

18. The method of claim 16, wherein the dilute nitride layer comprises GaInNAs, GaNAsSb, GaInNAsSb, GaInNAsBi, GaNAsSbBi, GaNAsBi, or GaInNAsSbBi.

19. A method of forming a semiconductor optoelectronic device, comprising:
forming a substrate;
forming an etch-stop/release layer overlying the substrate;
forming a first doped III-V layer overlying the etch-stop/release layer;
forming an active region overlying the first doped III-V layer, wherein the active region comprises a lattice matched dilute nitride layer or pseudomorphic dilute nitride layer having a bandgap within a range from 0.7 eV and 1.0 eV and a minority carrier lifetime of 1 ns or greater;
forming a second doped III-V layer overlying the active region;
removing the substrate and the etch-stop/release layer; and
forming a luminescent layer underlying the first doped III-V layer.

20. The method of claim 19, wherein the semiconductor optoelectronic device is configured to absorb wavelengths between 0.2 μm and 1.24 μm.
